(19) United States
(12) Patent Application Publication
(10) Pub. No.: US 2022/0135420 A1
(43) Pub. Date: May 5, 2022

(54) METHOD OF PREPARATION OF ZINC OXIDE NANOPARTICLES, ZINC OXIDE NANOPARTICLES OBTAINED BY THIS METHOD AND THEIR USE

(71) Applicant: Nanoxo sp. zo.o., Warszawa (PL)

(72) Inventors: Janusz Zbigniew LEWINSKI, Józefów (PL); Malgorzata WOLSKA-PIETKIEWICZ, Warszawa (PL); Maria JEDRZEJEWSKA, Warszawa (PL)

(21) Appl. No.: 17/609,049

(22) PCT Filed: May 15, 2020
(86) PCT No.: PCT/PL2020/000046

§ 371 Date: Nov. 5, 2021

(30) Foreign Application Priority Data
May 15, 2019 (PL) P.429943

(51) Int. Cl. C01G 9/02

(52) U.S. Cl. CPC C01G 9/02; B82Y 30/00

(57) ABSTRACT

The subject matter of the invention is a method of a preparation of zinc oxide nanoparticles, in which the organozinc precursor in an aprotic organic solvent is subjected to an oxidizing agent. A compound of the formula [R₂ZnLₙ]ₘ is used as the organozinc precursor, where R is C1-C5 alkyl, straight or branched, benzyl, phenyl, mesityl, cyclohexyl group, L is low-molecular-weight organic compound containing one Lewis base center of formula (I) or of formula (2) or of formula (3), where R¹, R² and R³ are C1-C5 alkyl, straight or branched, phenyl, benzyl, tolyl, mesityl or vinyl group, in which any hydrogen atom may be substituted by fluorine, chlorine, bromine or iodine atom, n is 0, 1 or 2, m is a natural number from 1 to 10. Furthermore, the subject matter of the invention are also zinc oxide nanoparticles obtained by the said method. Moreover, the subject matter of the invention is also the use of the disclosed zinc oxide nanoparticles in sensors or as ETL layers for the construction of solar cells, or as UV filters, or as materials for use in electronics or in catalysis.

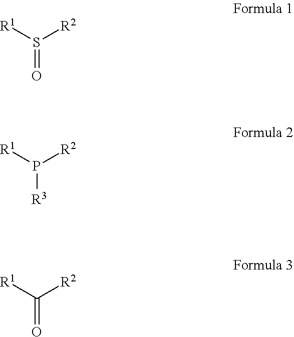

The subject matter of the invention is a method of a preparation of zinc oxide nanoparticles (ZnO NPs) stabilized by neutral short-chain organic donor ligands, zinc oxide nanoparticles obtained by the said method as well as their use. The use of ligands of the said type is intended to produce a stable inorganic-organic hybrid systems characterized by the thinnest possible organic coating and/or the smallest possible content of the stabilizing layer on the surface of ZnO NPs.

Nanocrystalline ZnO belongs to a semiconductors of the II-VI semiconductors group and it is currently one of the most intensively studied nanomaterials as well as having a wide applicability. This results from the unique physicochemical properties of this material, such as: high mechanical strength, electrical conductivity as well as interesting piezoelectric, and luminescent properties.[1] The integral features of the nanocrystalline zinc oxide are determined by many factors, such as: (i) purity and chemical composition of the obtained material, (ii) crystalline structure, size and shape of an inorganic core and (iii) the presence, the degree of a surface coverage and physicochemical properties of the additional stabilizing layer (organic or inorganic). Said parameters are, however, largely determined by an application of an appropriate synthetic procedure.

There are several chemical methods of a synthesis of ZnO NPs that are currently commonly known and used, among which we can distinguish wet-chemical and dry (i.e. mechanochemical) methods. Due to the nature of a precursor, chemical methods can be divided into procedures using inorganic and organometallic precursors. Traditional, the simplest and currently the most often used inorganic chemical method for the preparation of ZnO NPs is the sol-gel procedure, which is based on a hydrolytic decomposition of inorganic salts, that are soluble in water and in polar systems, containing Zn²⁺ ions as well as relatively simple anions, such as e.g. nitrate or acetate.[2] The reaction proceeds in an alkaline environment (e.g. ROH/LiOH system) and usually in the presence of an additional surfactants, and the hydrolysis and condensation processes occur almost in parallel. Eventually, physicochemical properties of the final product are strictly dependent on the process parameters, such as i.a. temperature, time, amount and type of the applied solvent, and the pH of the resulting solution. [3] Disadvantages of this method are in turn low repeatability and reproducibility of the synthetic process. Moreover, a very fast nucleation and a lack of possibility to sufficiently control the initial growth of ZnO NPs significantly affect both the structure and the degree of surface coverage of nanoparticles as well as the uniformity and stability of the organic layer.

An alternative to the classical inorganic synthesis appeared to be the organometallic pathway. Particularly important is a method developed by Chaudret's team,[4] in which stable in an organic environment ZnO nanoparticles of controlled size and shape can be obtained by decomposition of Zn(c-C₆H₁₁)₂ at room temperature and under the exposition to humid air conditions (US 2006/0245998). In addition, in the said method the presence of a surfactant, usually in great excess, that acts both as a surface stabilizer and as a modulator of ZnO NPs growth and solubility is indispensable. According to invention US 2006/0245998 organic molecules with an alkyl group containing from 6 to 20 carbons, i.e. amines (especially primary amines), carboxylic acids, thiols, phosphorous compounds, ethers can be used as ligands, and anhydrous organic solvents such as THF, toluene, anisole, heptane are used as solvents. According to the authors of the invention, the shape and the size of ZnO NPs are controlled by the conditions of the conduct of the synthesis, which are: the nature of the used organometallic precursor, the character of the ligand, the type of the solvent, and the reaction time. However, the method according to patent US 2006/0245998 as a result of a direct exposure of a solution of dialkyl zinc precursor in an organic solvent does not allow to obtain ZnO NPs in a controlled manner.

In 2012, the next organometallic method of the preparation of ZnO nanostructures stabilized by monoanionic carboxylate or phosphinate ligands was described. For this purpose, the authors used a reaction system containing Et₂Zn as well as selected zinc dicarboxylates or zinc diorganophosphinates in an appropriate stoichiometric ratio, which allow avoidance of the excess of stabilizing agent in the solution. The hydrolysis was carried out in toluene at room temperature by addition of a solution of water in acetone or by water diffusion from a controlled humidity environment.[5] In the abovementioned reaction, high purity ZnO NPs with a wurtzite structure and a core size of 3-4 nm were obtained.

As a result of the research carried out in the Lewiliski's team, a general method of the preparation of ZnO NPs with a well-protected surface and stabilized by monoanionic organic ligands was developed.[6,7] The main assumption of the developed procedure is the use, in the synthesis of ZnO NPs, organozinc [RZn-X]-type complexes (where X—monoanionic organic ligand, e.g. RCO₂⁻, RCONH⁻, R₂PO₂⁻, RO⁻) as an organometallic precursors, which constitute both: a source of Zn and an organic ligand. The used RZn-X precursors comprise in their structure both (1) the Zn-R moieties reactive toward oxygen and water (as oxygen sources) and (ii) the deprotonated auxiliary ligand bound to the Zn atom, which covalently attached to the nanoparticle's surface performs a stabilizing function. The transformation toward ZnO NPs occurs at room temperature as a result of direct, controlled exposure of the precursor solution to air conditions. It leads to slow oxidation and hydrolysis of catalytic centers and self-organization processes that result in the formation of ZnO NPs stabilized with monoanionic forms of parent proligand. The developed OSSOM method (ang. one-pot self-supporting organometallic approach) allows the synthesis of stable, non-metal doped crystalline structures exhibiting luminescent properties and allows the preparation of nanoparticles with specific morphology, shape and size.[6,7]

Nanocrystalline ZnO has a relatively active surface and exhibits the tendency to aggregate and/or agglomerate. Therefore, there is a need for an effective passivation and/or stabilization of ZnO NPs surface. For this purpose, NPs surface modification and formation of the so-called protective coat composed of hydrophobic, hydrophilic or amphiphilic compounds [8] or creation of a core-shell structure, i.e. coating of the NP core with a thin layer of another inorganic compound (e.g. ZnS,[9] TiO₂ or SiO₂ [10]) are used. There are many examples of organic compounds that can stabilize the surface of ZnO nanoparticles including polimers,[11,12] liquid crystalline systems,[13] surfaktants,[4] fatty acids [14] and long-chain alkylamines,[4,15] alkylthiols [16], as well as phosphine oxides (e.g. trioctylphosphine oxide, TOPO).[16,17] Despite significant differentiation, all of the above groups can perform the function of neutral donor L-type ligands (or a mixed function of L-type and anionic X-type ligands simultaneously, depending on the form in which the molecule is present) interacting with ZnO NPs surface on the basis of chemisorption. A characteristic feature of these compounds is also the presence of long-chain alkyl groups (C6-C20) in the structure, which significantly affects the surface stabilization and the ability to regulate the solubility of the nanomaterial through the interactions between ligand molecules and/or solvent molecules. However, the use of L-type ligands does not allow to obtain a sufficient stabilization due to a relatively low surface coverage of ZnO NPs. [18] Furthermore, in order to use of ZnO NPs in sensors or as electron transfer layers (ETLs) for the construction of solar cells, or as UV filters, or as materials for use in electronics or in catalysis, a relatively high organic content is not a desirable feature. On the other hand, the creation of a core-shell structure cause a significant reduction of the solubility of the system in various solvents. Therefore, there is a great interest in the development of a method of the synthesis of ultra-small (1-10 nm), stable and dispersed in solution hybrid systems with the smallest possible content of an organic stabilizing layer.

The object of the invention was to develop a method of preparation of inorganic-organic hybrid systems characterized by reduced organic stabilizing content on the surface of ZnO NPs. This goal has been achieved by the use of simple organic compounds with solvating and/or coordinating properties as an effective L-type stabilizing ligands. The use of such ligands has not been considered to date.

The method of a preparation of zinc oxide nanoparticles according to the invention is characterized by the fact that an organozinc precursor in an aprotic organic solvent is exposed to an oxidizing agent, wherein a compound of formula [R₂ZnLₙ]ₘ is used as the organozinc precursor, in which. R is C1-C5 alkyl, straight or branched, benzyl, phenyl, mesityl, cyclohexyl group, L is low-molecular-weight organic compound containing one Lewis base center of formula 1 or of formula 2 or of formula 3,

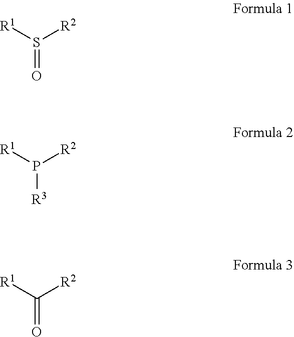

where R¹, R² and R³ are C₁ -C5 alkyl, straight or branched, phenyl, benzyl, tolyl, mesityl or vinyl group, in which any hydrogen atom may be substituted by fluorine, chlorine, bromine or iodine atom, n is 0, 1 or 2, m is a natural number from 1 to 10.

Preferably as the solvent aprotic organic solvents with solvating and/or coordinating properties are used: dimethyl sulfoxide, dibuthyl sulfoxide, tetrahydrofuran, dichloromethane, dioxane, acetonitrile, chloroform, toluene, benzene, hexane, acetone and other organic solvent without hydroxyl group in the structure, in which the precursor is well-soluble, as well as mixtures of such solvents.

Preferably when a liquid compound is used as L, it has a function of both a L-type ligand and an aprotic solvent for the organozinc precursor.

In the method of this invention an anhydrous organic solvent or solvent with the addition of water can be used. Preferably the concentration of water in the solvent should not exceed 0.5% w/w. The addition of water to the organic solvent has a positive effect on the formation rate of ZnO NPs and the photoluminescent properties of the resulting ZnO NPs as well as their dispersion.

Preferably oxygen, water, atmospheric air or a mixture of thereof is used as the oxidizing agent.

Preferably the reaction is carried out at temperature from 0° C. to 100° C., more preferably from 10° C. to 60° C., the most preferably from 15° C. to 35° C.

Preferably the reaction is carried out at a molar concentration of the precursor in an organic solvent from 0.01 mol/L to 0.4 mol/L.

Preferably the reaction is carried out from 24 to 336 hours.

Preferably in order to obtain a high-quality ZnO NPs, a process of washing the excess of organic ligand is used.

Preferably toluene, benzene, xylene, tetrahydrofuran, dioxane, diethyl ether, hexane, dichloromethane, methanol, ethanol or mixtures thereof are used as the solvent for washing the excess of organic ligand.

The subject matter of the invention are also zinc oxide nanoparticles obtained by the said method.

Preferably zinc oxide nanoparticles are stabilized by neutral short-chain organic donor ligands, wherein neutral short-chain organic donor ligands are compounds of formula 1 or of formula 2 or of formula 3,

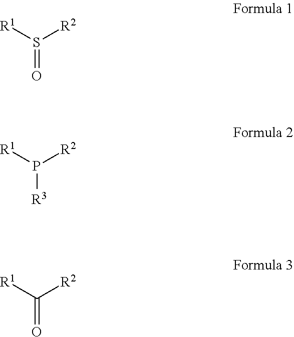

where R¹, R² and R³ are C1 -C5 alkyl, straight or branched, phenyl, benzyl, tolyl, mesityl or vinyl group, in which any hydrogen atom may be substituted by fluorine, chlorine, bromine or iodine atom, preferably neutral short-chain organic donor ligands are sulfoxides, the most preferably dimethyl sulfoxide.

Preferably the diameter of the zinc oxide nanoparticles is less than or equal to 15 nm and is characterized by a narrow size distribution.

Preferably nanoparticles have a wurtzite core structure.

The present invention also relates to the use of the zinc oxide nanoparticles disclosed above or zinc oxide nanoparticles obtained by the method disclosed above in sensors or as ETL layers for the construction of solar cells, or as UV filters, or as materials for use in electronics or in catalysis.

In the method according to the invention dialkylzinc compounds R₂Zn or organometallic compounds of R₂ZnLₙ-type were used, those compounds may occur in a monomeric or an aggregated [R₂ZnLₙ]ₘ-type form. The applied R₂ZnLₙ-type precursors contain in their structure dialkylzinc moieties R₂Zn, which are stabilized by neutral aprotic ligands of a relatively simple structure and low molecular weight. The use of such low-molecular-weight organic compounds, containing one Lewis basic center, allows the formation of inorganic-organic hybrid systems, characterized by the lowest possible content of organic layer stabilizing the surface of ZnO NPs. In addition, the above compounds, which occur in a liquid state and are characterized by solvating and/or coordinating properties, can have a dual function: they are both a reaction medium for the reaction using R₂Zn compounds and as an L-type organic ligand that effectively passivate the surface of obtained ZnO NPs. Simultaneously, by using a solvent/ligand with coordinating properties, the addition of an external stabilizing agent in the form of e.g. a long-chain surfactant was omitted. As a result of the reaction of the precursor with water and oxygen, it is possible to obtain ZnO NPs stabilized by short-chain organic ligands, which exhibit luminescent properties both in the solution and in the solid state. The use of low-molecular-weight ligands in the organometallic method is an alternative to long-chain organic compounds with surface-active and stabilizing properties. Measurements using various analytical techniques confirmed the presence of nano-sized objects with a core size within a few nanometers (2-10 nm) characterized by (in some cases) a tendency to aggregate in solution. In comparison with surfactants (e.g. alkylamines), low-molecular-weight neutral donor ligands exhibit higher affinity to the surface of ZnO NPs, which results in an increase of a system stability in time while maintaining their integral photophysical properties. Depending on the reaction conditions: concentration, time, reaction temperature, type of the solvent used, oxygen and water concentration, etc., it is possible to obtain a variety of forms of nanocrystalline zinc oxide. The method according to the invention allows for a significant simplification of the reaction system and opens up new possibilities in the design and synthesis of functional ZnO-based materials.

The drawing shows:

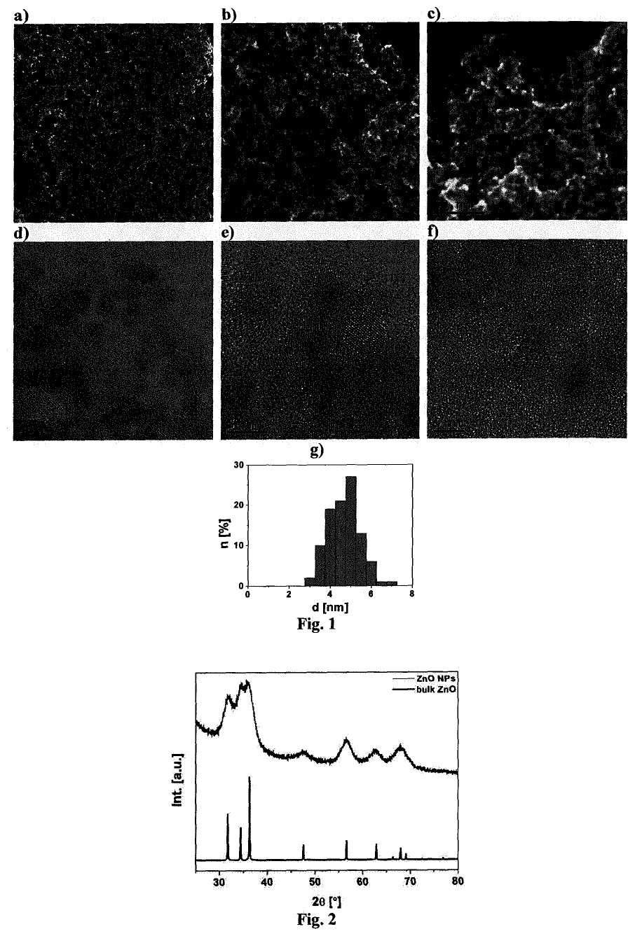

FIG. 1—SE (a-c) and HR TEM (d-f) images of ZnO.L1 NPs as well as (g) size distribution of the obtained nanoparticles (Example 1).

FIG. 2—Powder X-ray diffraction pattern of ZnO.L1 NPs together with a reference bulk ZnO pattern (Example 1).

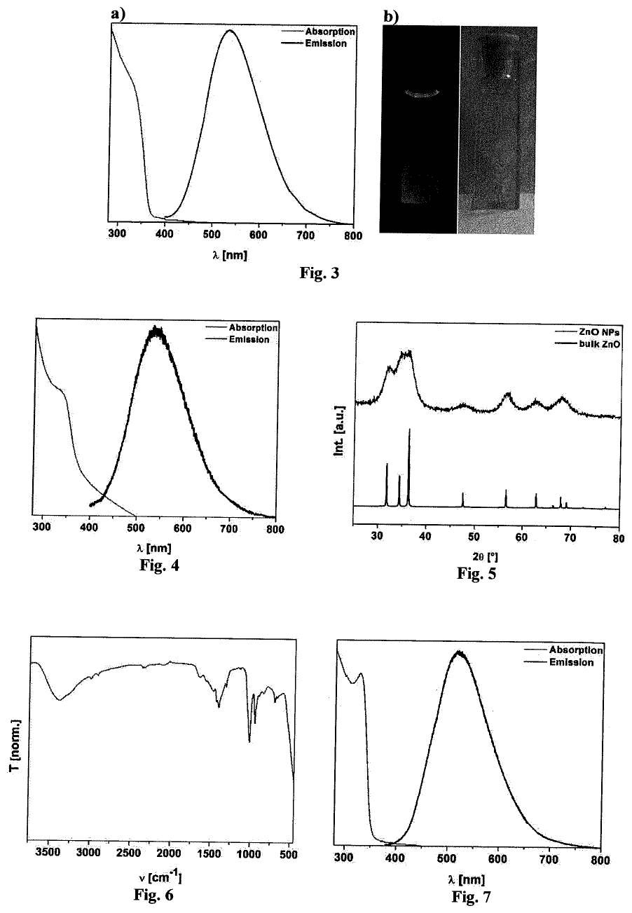

FIG. 3—a) Normalized absorption and emission spectra of ZnO.L1 NPs; b) UV (366 nm) and visible light images of a stable colloidal solution of ZnO.L1 NPs (Example 1).

FIG. 4—Normalized absorption and emission spectra of ZnO.L2 NPs (Example 3).

FIG. 5—Powder X-ray diffraction pattern of ZnO.L2 NPs together with a reference bulk ZnO pattern (Example 3).

FIG. 6—IR spectrum of ZnO.L2 NPs (Example 3).

FIG. 7—Normalized absorption and emission spectra of ZnO.L3 NPs (Example 4).

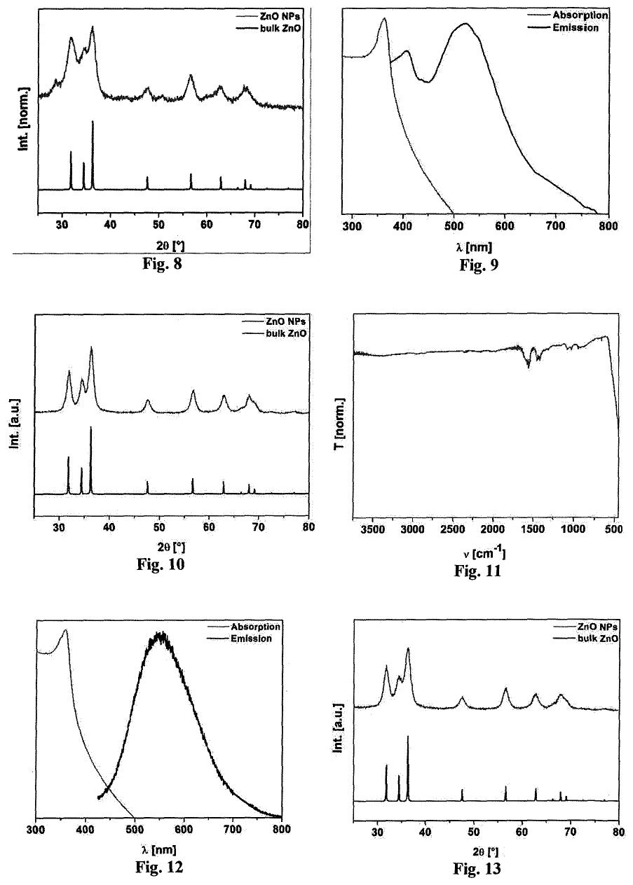

FIG. 8—Powder X-ray diffraction pattern of ZnO.L3 NPs together with a reference bulk ZnO pattern (Example 4).

FIG. 9—Normalized absorption and emission spectra of ZnO.L4 NPs (Example 5).

FIG. 10—Powder X-ray diffraction pattern of ZnO.L4 NPs together with a reference bulk ZnO pattern (Example 5).

FIG. 11—IR spectrum of ZnO.L4 NPs (Example 5).

FIG. 12—Normalized absorption and emission spectra of ZnO.L5 NPs (Example 6).

FIG. 13—Powder X-ray diffraction pattern of ZnO.L5 NPs together with a reference bulk ZnO pattern (Example 6).

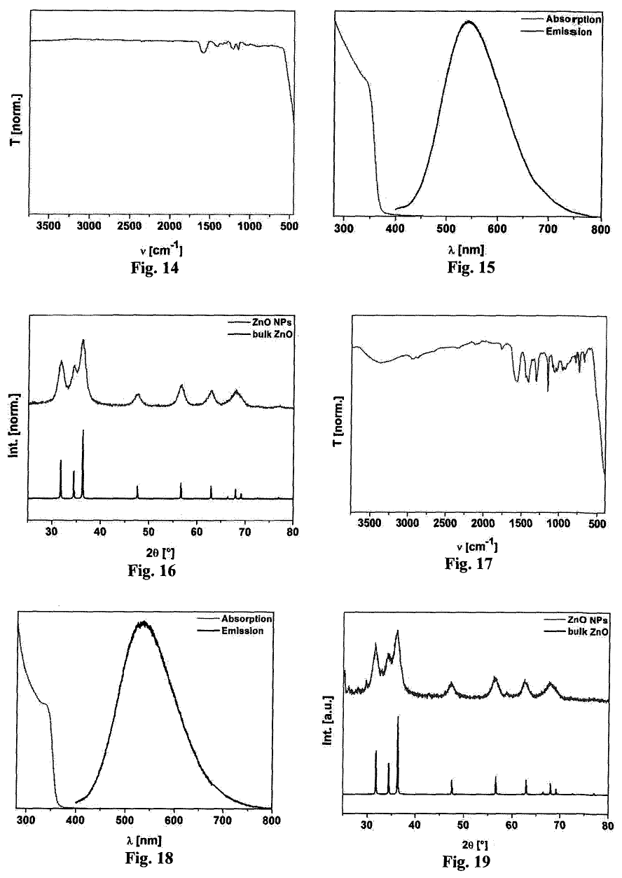

FIG. 14—IR spectrum of ZnO.L5 NPs (Example 6).

FIG. 15—Normalized absorption and emission spectra of ZnO.L6 NPs (Example 7).

FIG. 16—Powder X-ray diffraction pattern of ZnO.L6 NPs together with a reference bulk ZnO pattern (Example 7).

FIG. 17—IR spectrum of ZnO.L6 NPs (Example 7).

FIG. 18—Normalized absorption and emission spectra of ZnO.L7 NPs (Example 9).

FIG. 19—Powder X-ray diffraction pattern of ZnO.L7 NPs together with a reference bulk ZnO pattern (Example 9).

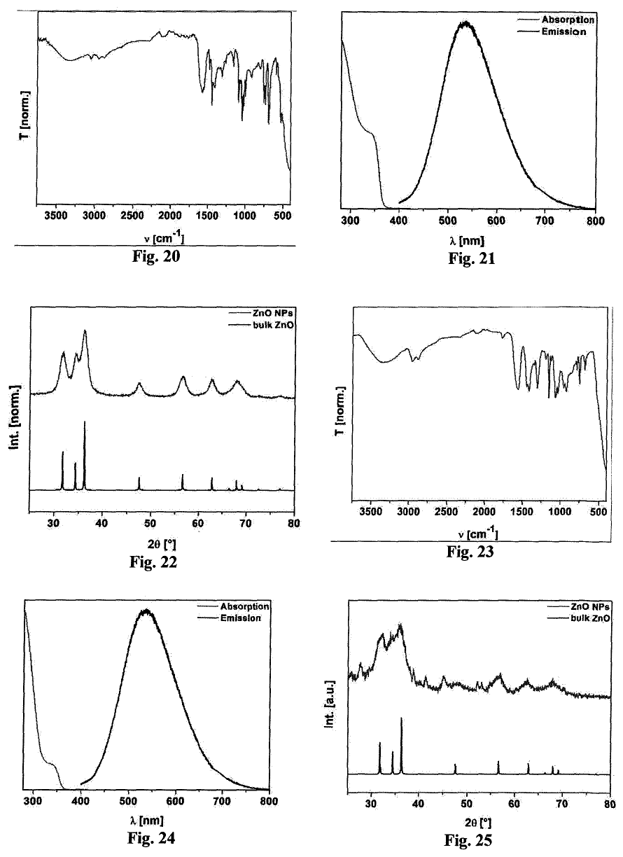

FIG. 20—IR spectrum of ZnO.L7 NPs (Example 9).

FIG. 21—Normalized absorption and emission spectra of ZnO.L8 NPs (Example 10).

FIG. 22—Powder X-ray diffraction pattern of ZnO.L8 NPs together with a reference bulk ZnO pattern (Example 10).

FIG. 23—IR spectrum of ZnO.L8 NPs (Example 10).

FIG. 24—Normalized absorption and emission spectra of ZnO.L9 NPs (Example 11).

FIG. 25—Powder X-ray diffraction pattern of ZnO.L9 together with a reference bulk ZnO pattern (Example 11).

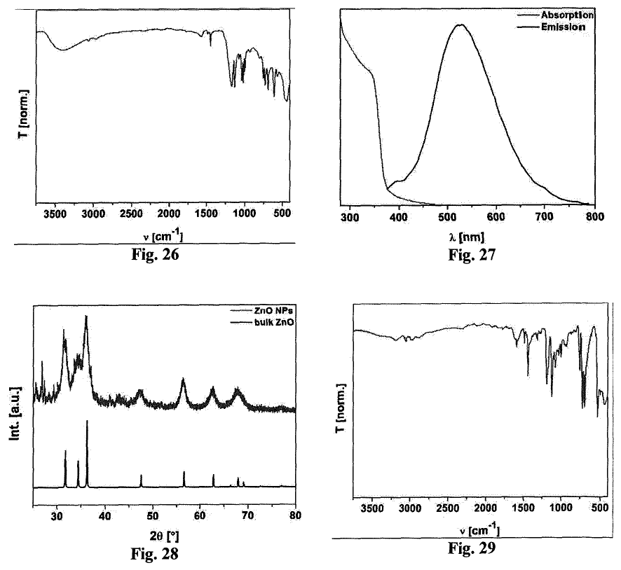

FIG. 26—IR spectrum of ZnO.L9 NPs (Example 11).

FIG. 27—Normalized absorption and emission spectra of ZnO.L10 NPs (Example 12).

FIG. 28—Powder X-ray diffraction pattern of ZnO.L10 NPs together with a reference bulk ZnO pattern (Example 12).

FIG. 29—IR spectrum of ZnO.L10 NPs (Example 12).

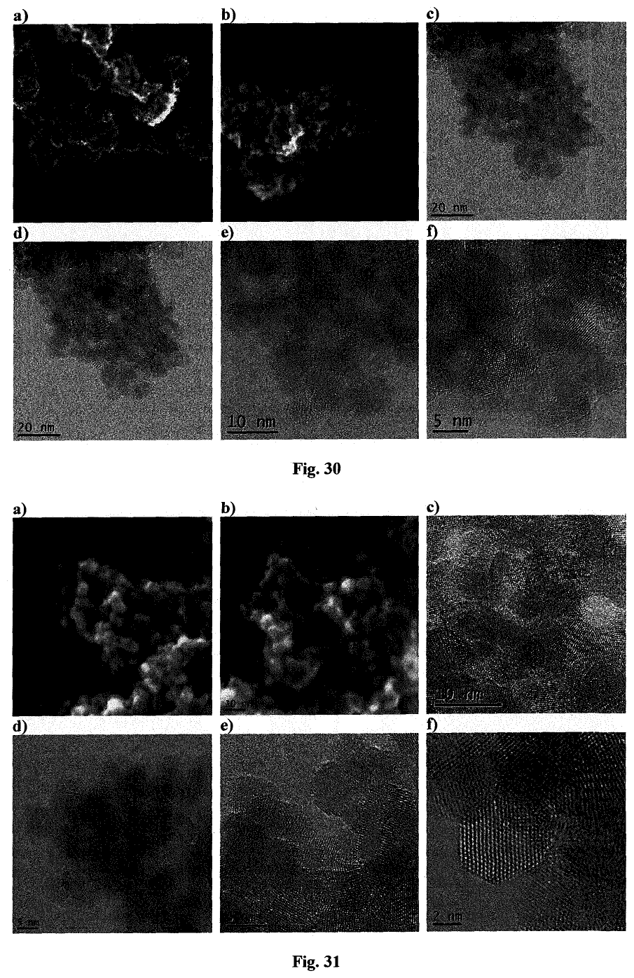

FIG. 30—SE (a-b) and HR TEM (c-f) images of ZnO.L11 NPs (Example 14).

FIG. 31—SE (a-b) and HR TEM (c-f) images of ZnO.L12 NPs (Example 15).

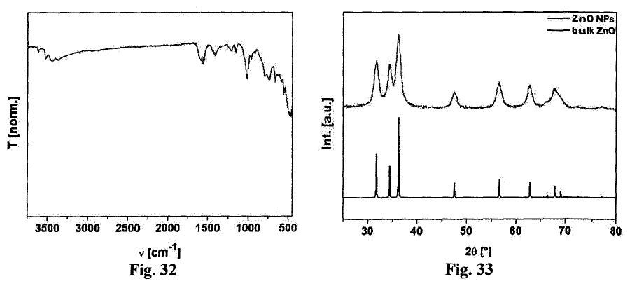

FIG. 32—IR spectrum of ZnO.L13 NPs (Example 16).

FIG. 33—Powder X-ray diffraction pattern of ZnO.L13 NPs together with a reference bulk ZnO pattern (Example 16).

The subject matter of the invention is presented in more detail in the following examples.

### Example 1

### The Preparation of ZnO NPs as a Result of a Direct Exposition of a Solution of Et₂Zn in Dimethyl Sulfoxide (DMSO) to Atmospheric Air

1 mL of 2M Et₂Zn (a solution in hexane) was added dropwise at room temperature to 20 mL of dimethyl sulfoxide placed in a 50 mL round-bottom flask equipped with a magnetic stirring bar. The reaction mixture was subjected to controlled exposure to atmospheric air for 24 48 hrs at ambient temperature. After this time, a suspension exhibiting an intense yellow fluorescence under UV excitation was obtained. The precipitate was separated by centrifugation (15 min, 12500 rpm) and a stable colloidal solution was obtained. ZnO nanoparticles can also be purified by a precipitation method from the post-reaction mixture with acetone, and further by washing the resulting precipitate 3 times with small portions of acetone. The nanocrystalline ZnO obtained as a result of controlled transformation (hereinafter referred to as ZnO.L1 NPs) was characterized by a wide range of analytical techniques such as: high resolution scanning transmission electron microscopy (STEM), powder X-ray diffraction (PXRD), dynamic light scattering (DLS), infrared spectroscopy (FTIR), UV-Vis spectrophotometry and spectrofluorometry (PL).

STEM images of the resulting ZnO nanoparticles that were taken in the immersion mode, which records the signal of secondary electrons (SE) and allows the morphological study of the nanoparticles as well as in a mode that allows the characterization of both the structure and the chemical composition at the atomic scale (HR TEM) along with the size distribution of the inorganic ZnO.L1 NPs core are shown in FIG. 1. These micrographs show a nanocrystalline ZnO aggregates composed of single quasi-spherical nanocrystallites of a size of several nanometers (2-7 nm), which indicates a narrow size distribution of the resulting ZnO.L1 NPs. DLS analysis has shown that the average size of ZnO.L1 NPs aggregates present in the DMSO solution is about 103 nm, and the relatively low polydispersity index (PdI=0.28) indicates a high similarity, almost uniform shape and a narrow size distribution of the hydrodynamic diameter of the obtained nanostructures. Aside from size, very important features of NPs are their chemical composition and crystalline structure of the core. PXRD analysis (FIG. 2) confirmed nanocrystalline (i.e. NPs diameter<15 nm), wurtzite-type structure of ZnO.L1 NPs. FTIR analysis allowed the determination of the coordination mode a L-type ligand, here DMSO, to the surface of ZnO NPs. The presence of a strong band at 1017 cm⁻¹ is characteristic for the bending vibrations of the S═O bond and indicates the coordination of DMSO to the surface of the inorganic ZnO core via an oxygen atom. Additionally, the band at 3404 cm⁻¹ is characteristic for stretching vibrations of O—H bond. The position of the hydroxyl group band in Zn(OH)₂ is very similar, i.e. 3384 cm⁻¹. Thus, on the surface of the inorganic core there are not only coordinated DMSO molecules, but also Zn—OH moieties being the result of the reaction between dialkylzinc compound and water present in the air. Based on the position and the shape of the band of OH group, it can be concluded that there are hydrogen bonds between the Zn—OH group and DMSO molecule in the system. ZnO.L1 NPs exhibit the photoluminescent properties both in the solid state and in the solution (FIG. 3). The absorption and the emission spectra of the colloidal solution of ZnO.L1 NPs in DMSO are shown in FIG. 3a. In the region of 290 - 370 nm, a wide absorption band with the maximum located at 330 nm is visible. By contrast, a relatively wide emission band (with a half width (FWHM) of about 135 nm) is in the green light area (λₑₘ=531 nm) (FIG. 3a). The colloidal solution of ZnO.L1 NPs in DMSO is stable over time and no changes are observed (e.g. appearance of sediment at the bottom of the vessel) even after 9 months of storage.

### Example 2

### The Preparation of ZnO NPs as a Result of a Direct Exposition of a Solution of Me₂Zn in DMSO to Atmospheric Air

1 mL of 2M Me₂Zn (a solution in hexane) was added dropwise at room temperature to 20 mL of dimethyl sulfoxide placed in a 50 mL round-bottom flask equipped with a magnetic stirring bar. Then, the reaction mixture was subjected to a controlled exposure to atmospheric air for 7 days at ambient temperature. The as-prepared ZnO nanoparticles exhibit a similar physicochemical properties to those observed for ZnO.L1 NPs.

### Example 3

### The Preparation of ZnO NPs as a Result of a Direct Exposition of a Solution of iPr₂Zn in DMSO to Atmospheric Air

1 mL of 1M iPr₂Zn (a solution in toluene) was added dropwise to 20 mL of dimethyl sulfoxide placed in a 50 mL round-bottom flask equipped with a magnetic stirring bar. Then, the reaction mixture was subjected to a controlled exposure to atmospheric air for 5 days at ambient temperature. ZnO.L2 nanoparticles exhibit the photoluminescent properties both in the solution and in the solid state. The absorption and emission spectra of ZnO.L2 NPs dispersed in DMSO are shown in FIG. 4. The obtained system is characterized by a well-defined absorption band with the maximum at 345 nm as well as by a relatively wide emission band with the maximum at 531 nm (FIG. 4). Based on PXRD analysis (FIG. 5) nanocrystalline, wurtzite-type structure of ZnO.L2 NPs was confirmed. The presence of passivating, coordinated to the surface of ZnO core DMSO moieties was confirmed via FTIR measurement (FIG. 6).

### Example 4

### The Preparation of ZnO NPs as a Result of Direct Exposition of a Solution of Et₂Zn in Dibuthyl Sulfoxide to Atmospheric Air

1 mL of 2M Et₂Zn (a solution in hexane) was added dropwise at room temperature to 20 mL of dibuthyl sulfoxide placed in a 50 mL round-bottom flask equipped with a magnetic stirring bar. Then, the reaction mixture was subjected to a controlled exposure to atmospheric air for 5 days at ambient temperature. The obtained ZnO.L3 NPs exhibit the photoluminescent properties both in the solution and in the solid state. The absorption and emission spectra of ZnO.L₃ NPs are shown in FIG. 7. The obtained system is characterized by a well-defined absorption band with the maximum at 343 nm. A relatively wide emission band with a maximum at 515 nm is responsible for the green fluorescence of ZnO.L3 NPs (FIG. 7). Based on the PXRD analysis (FIG. 8) nanocrystalline, wurtzite-type structure of ZnO L3 NPs was confirmed.

### Example 5

### The Preparation of ZnO NPs Stabilized by DMSO Ligand

156 mg (2 mmol) (CH₃)₂SO in 10 mL of THF was placed in a Schlenk vessel equipped with a magnetic stirring bar. It was cooled in an isopropanol bath to −78° C. Then, in an inert gas atmosphere, 1 mL of 2M (2 mmol) Et₂Zn (a solution in hexane) was added dropwise via a syringe. The reaction was initially carried out at reduced temperature and then gradually warmed to room temperature and left at this temperature for 24 hours. Then, the reaction mixture was subjected to control exposure to atmospheric air for 5 days at ambient temperature. Nanoparticles ZnO.L4 NPs exhibit the luminescent properties both in the solution and in the solid state. The absorption and emission spectra of ZnO.L3 NPs dispersion are shown in FIG. 9. Based on PXRD analysis (FIG. 10) nanocrystalline, wurtzite-type structure of ZnO.L4 NPs was confirmed. Similarly as it is in the case of Zn0.1, 1 and ZnO.L2 NPs, FTIR analysis confirmed the presence of an organic layer composed of DMSO molecules on the surface of the nanocrystalline ZnO (FIG. 11).

### Example 6

### The Preparation of ZnO NPs Stabilized by DMSO Ligand using iPr2Zn as an Organometallic Precursor

78 mg (1 mmol) (CH₃)₂SO in 10 mL of THF was placed in a Schlenk vessel equipped with a magnetic stirring bar. Then, in an inert gas atmosphere, 1 mL of 1M (2 mmol) iPr₂Zn (a solution in toluene) was added dropwise via a syringe. The reaction was carried out at room temperature and stirred for 24 hours. After this time, the reaction mixture was subjected to a controlled exposure to atmospheric air for 5 days at ambient temperature. Nanoparticles ZnO.L5 NPs exhibit the luminescent properties both in the solution and in the solid state. The absorption and emission spectra of ZnO.L5 NPs dispersion are shown in FIG. 12. Based on PXRD analysis (FIG. 13) nanocrystalline, wurtzite-type structure of ZnO.L5 NPs was confirmed. The lack of additional reflections on the powder X-ray diffraction pattern indicates a high degree of sample purity. Similarly as it is in the case of ZnO.L1 and ZnO.L3 NPs, FTIR analysis confirmed the presence of an organic layer composed of DMSO molecules on the surface of the nanocrystalline ZnO (FIG. 14).

### Example 7

The Preparation of ZnO NPs Stabilized by (CH₃(CH₂)₃)₂SO) ligand.

324 mg (1 mmol) (CH₃(CH₂)₃)₂SO in 10 mL of THF was placed in a Schlenk vessel equipped with a magnetic stirring bar. It was cooled in an isopropanol bath to −78° C. Then, in an inert gas atmosphere, 0.5 mL of 2M (1 mmol) Et₂Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 5 days at ambient temperature. Nanoparticles ZnOL6 NPs exhibit the luminescent properties both in the solution and in the solid state. The absorption and emission spectra of ZnO. L6 NPs dispersion are shown in FIG. 15. Based on PXRD analysis (FIG. 16) nanocrystalline, wurtzite-type structure of ZnOL6 NPs was confirmed whereas MIR analysis confirmed the presence of an organic layer composed of dibuthyl sulfoxide molecules on the surface of the nanocrystalline ZnO (FIG. 17). Changes in both intensity and shifts of the bands characteristic for (CH₃(CH₂)₃)2SO in IR spectrum indicate the coordination of sulfoxide ligands to the surface of ZnO NPs.

### Example 8

### The Preparation of ZnO NPs Stabilized by (CH₃(CH₂)₃)₂SO Ligand using tBu₂Zn as an Organometallic Precursor

324 mg (1 mmol) (CH₃(CH₂)₃)₂SO in 10 mL of THF was placed in a Schlenk vessel equipped with a magnetic stirring bar. It was cooled in an isopropanol bath to −78° C. Then, in an inert gas atmosphere, 1 mL of 1M (1 mmol) tBu₂Zn (a solution in toluene) was added dropwise via a syringe. The reaction was initially carried out at reduced temperature and then gradually warmed to room temperature and left at this temperature for 24 hours. Then, the reaction mixture was subjected to a controlled exposure to atmospheric air for 8 days at ambient temperature. The as-prepared ZnO nanoparticles exhibit a similar physicochemical properties to those observed for ZnO.L6 NPs.

### Example 9

### The Preparation of ZnO NPs Stabilized by Diphenylsulfoxide Ligand

404 mg (2 mmol) (C₆H₅)₂S in 10 mL of THF was placed in a Schlenk vessel equipped with a magnetic stirring bar. It was cooled in an isopropanol bath to −78° C. Then, in an inert gas atmosphere, 1 mL of 2M (2 mmol) Et2Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 5 days at ambient temperature. ZnO.L7 NPs were obtained as a powder that exhibit yellow fluorescence under UV excitation. The absorption and emission spectra of ZnO.L7 NPs dispersion are shown in FIG. 18. After decantation, ZnO nanoparticles were characterized by PXRD (FIG. 19). The powder X-ray diffraction pattern analysis confirmed the crystalline wurtzite structure of ZnO.L7 NPs. The additional reflections indicate the presence of the ligand phase in the sample, what was also confirmed by FTIR analysis (FIG. 20).

### Example 10

### The Preparation of ZnO NPs Stabilized by CH₃SOC₆H₅ Ligand

280 mg (2 mmol) CH₃SOC₆H₅ in 10 mL of THF was placed in a Schlenk vessel equipped with a magnetic stirring bar. It was cooled in an isopropanol bath to −78° C. Then, in an inert gas atmosphere, 1 mL of 2M (2 mmol) Et₂Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 5 days at ambient temperature. ZnO.L8 nanoparticles were obtained as a powder, which exhibits a yellow fluorescence with a maximum of emission located at 525 nm. The absorption and emission spectra of ZnO.L8 NPs dispersion are shown in FIG. 21. PXRD analysis (FIG. 22) confirmed nanocrystalline, wurtzite-type structure of ZnO.L8 NPs while the presence of the NPs organic stabilizing layer was confirmed based on FTIR analysis (FIG. 23).

### Example 11

### The Preparation of ZnO NPs Stabilized by C₆H₅SOCH═CH₂ Ligand

304 mg (2 mmol) C6H5SOCH=CH2 in 10 mL of THF was placed in a Schlenk vessel equipped with a magnetic stirring bar. It was cooled in an isopropanol bath to -78° C. Then, in an inert gas atmosphere, 1 mL of 2M (2 mmol) Et2Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 5 days at ambient temperature. ZnO L9 nanoparticles have luminescent properties. The absorption and emission spectra of ZnOL9 NPs dispersion are shown in FIG. 24. PXRD analysis indicates the nanocrystalline nature of the sample (FIG. 25), while FTIR analysis confirmed the presence of an organic layer consisting of sulfoxide molecules on the surface of the nanocrystalline ZnO (FIG. 26).

### Example 12

### The Preparation of ZnO NPs Stabilized by Triphenylphosphine

524 mg (2 mmol) P(C₆H₅)₃ in 10 mL of THF was placed in a Schlenk vessel equipped with a magnetic stirring bar. It was cooled in an isopropanol bath to −78° C. Then, in an inert gas atmosphere, 1 mL of 2M (2 mmol) Et₂Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 4 days at ambient temperature. ZnO.L10 nanoparticles have luminescent properties (FIG. 27). Based on PXRD analysis (FIG. 28) nanocrystalline, wurtzite-type structure of ZnO.L10 NPs was confirmed, while FTIR analysis confirmed the presence of an organic layer consisting of triphenylphosphine molecules on the surface of the nanocrystalline ZnO (FIG. 29).

### Example 13

### The Preparation of ZnO NPs Stabilized by Triphenylphosphine using Me₂Zn as an Organometallic Precursor

648 mg (2 mmol) (CH₃(CH₂)₃)₂SO in 10 mL of THF was placed in a Schlenk vessel equipped with a magnetic stirring bar. It was cooled in an isopropanol bath to −78° C. Then, in an inert gas atmosphere, 1 mL of 2M (2 mmol) Me₂Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 9 days at ambient temperature. The as-prepared ZnO nanoparticles exhibit a similar physicochemical properties to those observed for ZnO.L10 NPs.

### Example 14

### The Preparation of ZnO NPs as a Result of a Direct Exposition of a Solution of Et₂Zn in THF to Atmospheric Air

1 mL of 2M Et₂Zn (a solution in hexane) was added dropwise at room temperature to 20 mL of THF placed in a 50 mL round-bottom flask equipped with a magnetic stirring bar. The reaction mixture was subjected to a controlled exposure to atmospheric air for 2 days at ambient temperature. ZnO.L11 nanoparticles exhibit fluorescence both in the solution and in the solid state. Microscopic measurements showed the presence of ZnO NPs of the pseudo-spherical shape and of a size in the range of 1-7 nm as well as characterized by a relatively narrow size distribution (FIG. 30).

### Example 15

### The Preparation of ZnO NPs as a Result of a Direct Exposition of a Solution of Et₂Zn in Acetone to Atmospheric Air

1 mL of 2M Et₂Zn (a solution in hexane) was added dropwise at room temperature to 20 mL of acetone placed in a 50 mL round-bottom flask equipped with a magnetic stirring bar. The as-prepared reaction mixture was subjected to a controlled exposure to air for 3 days at ambient temperature, and then the obtained luminescent ZnO.L12 NPs was characterized. Microscopic measurements showed the presence of nanocrystalline ZnO with a core diameter in the range of 2-10 nm (FIG. 31).

### Example 16

### The Preparation of ZnO NPs Stabilized by (CH₃C₆H₄)₂S Ligand

460.6 mg (2 mmol) (CH₃C₆H₄)₂SO in 10 mL of THF was placed in a Schlenk vessel equipped with a magnetic stirring bar. It was cooled in an isopropanol bath to −78° C. Then, in an inert gas atmosphere, 1 mL of 2M (2 mmol) Et₂Zn (a solution in hexane) was added dropwise via a syringe. The reaction was initially carried out at reduced temperature and then gradually warmed to room temperature and left at this temperature for 24 hours. Then, the reaction mixture was subjected to a controlled exposure to atmospheric air for 5 days at ambient temperature. ZnO.L13 nanoparticles exhibit luminescent properties. FTIR analysis confirmed the presence of organic layer consisting of sulfoxide molecules on the surface of the nanocrystalline ZnO (FIG. 32). Based on PXRD analysis (FIG. 33) nanocrystalline, wurtzite-type structure of ZnO.L13 NPs was confirmed. The lack of additional reflections on the diffraction pattern indicates a high degree of sample purity.

### LITERATURE

[1] Morkoc, H.; Özgür, U. Zinc Oxide: Fundamentals, Materials and Device Technology, Willey-VCH, Weinheitn, 2009.
[2] Spanhel, L.; Anderson, M. A., Semiconductor Clusters in the Sol-Gel Process: Quantized Aggregation, Gelation, and Crystal Growth in Concentrated ZnO Colloids. J. Am. Chem. Soc. 1991, 113, 2826-2833.
[3] Meulenkamp, E. A., Synthesis and Growth of ZnO Nanoparticles. J. Phys. Chem. B 1998, 102, 5566-5572.
[4] a) Monge, M.; Kahn, M. L.; Maisonnat, A.; Chaudret, B., Room-Temperature Organometallic Synthesis of Soluble and Crystalline ZnO Nanoparticles of Controlled Size and Shape. Angew. Chem. Int. Ed. 2003, 42, 5321-5324; b) Kahn, M. L.; Monge, M.; Maisonnat, A.; Chaudret, B. French Patent CNRS, Fr03-042825, 2004; c) Patent US 2006/0245998, 2006.
[5] Orchard K. L.; Shaffer M. S. P.; Williams C. K., Organometallic Route to Surface-Modified ZnO Nanoparticles Suitable for In Situ Nanocomposite Synthesis: Bound Carboxylate Stoichiometry Controls Particle Size or Surface Coverage. Chem. Mater. 2012, 24, 2443-2448.
[6] a) Lewiński, J.; Bojarski, E.; Bury, W.; Kościelski, M., P-383356, 2007; b) Lewiński, J.; Bury, W.; Kościelski, M.; Bojarski, E., P-383357, 2007; c) Lewiński, J.; Suwala, K.; Kubisiak, M., P-385938, 2008; d) Lewiński, J.; Suwala, K., P-386289, 2008; e) Lewiński, J.; Sokolowski, K.; Leszczyński, M.; Zelga K., P-393834, 2011; f) Krupiński, P.; Komowicz, A.; Lewiński, J., P-402624, 2013.
[7] a) Paczesny, J.; Wolska-Pietkiewicz, M.; Binkiewicz, I.; Wróbel, Z.; Wadowska, M.; Matula, K.; Dziçcielewski, I.; Pociecha, D.; Smalc-Koziorowska, J.; Lewiński, J.; Holyst, R., Towards Organized Hybrid Nanomaterials at the air/water Interface Based on Liquid Crystal-ZnO Nanocrystals. Chem. Eur. J. 2015, 21, 16941-16947; b) Paczesny, J.; Wolska-Pietkiewicz, M.; Binkiewicz, I.; Wadowska, M.; Wróbel, Z.; Matula, K.; Nogala, W.; Lewiński, J.; Holyst, R., Photoactive Langmuir-Blodgett, Freely Suspended and Free Standing Films of Carboxylate Ligand-Coated ZnO Nanocrystals. ACS Appl. Mater. Interfaces, 2016, 8, 13532-13541; c) Grala, A.; Wolska-Pietkiewicz, M.; Danowski, W.; Wróbel, Z.; Grzonka, J.; Lewiński, J., ‘Clickable’ ZnO nanocrystals: the superiority of a novel organometallic approach over the inorganic sol-gel procedure. Chem. Commun. 2016, 52, 7340-7343; d) Wolska-Pietkiewicz, M.; Grala, A.; Justyniak, I.; Hryciuk, D.; Jçdrzejewska, M.; Grzonka, J.; Kurzydlowski, K. J., Lewiński, J., From well-defined alkylzinc phosphinates to quantum-sized ZnO nanocrystals. Chem. Eur. J. 2017, 49, 11856-11865; e) Chwojnowska, E.; Wolska-Pietkiewicz, M.; Grzonka, J.; Lewiński J., An Organometallic Route to Chiroptically Active ZnO Nanocrystals. Nanoscale, 2017, 9, 14782-14786; f) Wolska-Pietkiewicz, M.; Tokarska, K.; Grala, A.; Wojewódzka, A.; Chwojnowska, E.; Grzonka, J.; Cywiński, P.; Kruczala, K.; Sojka, Z.; Chudy, M.; Lewiński, J., ‘Safe-by-design’ ligand coated-ZnO nanocrystals engineered by an organometallic approach: unique physicochemical properties and low toxicity toward lung cells. Chem. Eur. J. 2018, 24, 4033-4042.
[8] Chang, J.; Waclawik, E. R., Colloidal Semiconductor Nanocrystals: Controlled Synthesis and Surface Chemistry in Organic Media. RSC Adv. 2014, 4, 23505-23527.
[9] Sookhakian, M.; Amin, Y. M.; Basirun, W. J.; Tajabadi, M. T.; Kamarulzaman, N., Synthesis, Structural, and Optical Properties of Type-II ZnO—ZnS Core-Shell Nanostructure. JOL 2014, 145, 244-252.
[10] Tang, X.; Choo, E. S. G.; Li, L.; Ding, J.; Xue, J., Synthesis of ZnO Nanoparticles with Tunable Emission Colors and Their Cell Labeling Applications. Chem. Mater. 2010, 22, 3383-3388.

[11] a) Xiong, H.-M.; Xu, Y.; Ren, Q.-G.; Xia, Y.-Y., Stable Aqueous ZnO@polymer Core-Shell Nanoparticles with Tunable Photoluminescence and Their Application in Cell Imaging. J. Am. Chem. Soc. 2008, 130, 7522-7523; b) Xiong, H.-M., ZnO Nanoparticles Applied to Bioimaging and Drug Delivery. Adv. Mater. 2013, 25, 5329-5335.
[12] a) Guo, L.; Yang, S. H.; Yang, C. L.; Yu, P.; Wang, J. N.; Ge, W. K.; Wong, G. K. L., Synthesis and Characterization of Poly(vinylpyrrolidone)-Modified Zinc Oxide Nanoparticles. Chem. Mater. 2000, 12, 2268-2274; b) Xiong, H. M.; Wang, Z. D.; Liu, D. P.; Chen, J. S.; Wang, Y. G.; Xia, Y. Y., Bonding Polyether onto ZnO Nanoparticles: an Effective Method for Preparing Polymer Nanocomposites with Tunable Luminescence and Stable Conductivity. Adv. Funct. Mater. 2005, 15, 1751-1756; c) Xiong, H. M.; Wang, Z. D.; Xia, Y. Y., Polymerization Initiated by Inherent Free Radicals on Nanoparticle Surfaces: a Simple Method of Obtaining Ultrastable (ZnO)Polymer Core-Shell Nanoparticles with Strong Blue Fluorescence. Adv. Mater. 2006, 18, 748-751; (d) Xiong, H.-M.; Xie, D.-P.; Guan, X.-Y.; Tan, Y.-J.; Xia, Y.-Y., Water-Stable Blue-Emitting ZnO@polymer Core-Shell Microspheres. J. Mater. Chem. 2007, 17, 2490-2496.
[13] a) Li, F.; Li, Q.; Chen, Y., Observations of Energy Transfer and Anisotropic Behavior in ZnO Nanoparticles Surface-Modified by Liquid-Crystalline Ligands. JOL 2012, 132, 2114-2121; b) Neaime, C.; Prevot, M.; Amela-Cortes, M.; Circu, V.; Grasset, F.; Folliot, H.; Molard, Y., Voltage-Driven Photoluminescence Modulation of Liquid-Crystalline Hybridized ZnO Nanoparticles. Chem. Eur. J. 2014, 20, 13770-13776.
[14] a) Fu, Y.-S.; Du, X.-W.; Kulinich, S. A.; Qiu, J.-S.; Qin, W.-J.; Li, R.; Sun, J.; Liu, J., Stable Aqueous Dispersion of ZnO Quantum Dots with Strong Blue Emission via Simple Solution Route. J. Am. Chem. Soc. 2007, 129, 16029-16033; (b) Rubio-Garcia, J.; Dazzazi, A.; Coppel, Y.; Mascalchi, P.; Salome, L.; Bouhaouss, A.; Kahn, M. L.; Gauffre, F., Transfer of Hydrophobic ZnO Nanocrystals to Water: an Investigation of the Transfer Mechanism and Luminescent Properties. J. Mater. Chem. 2012, 22, 14538-14545.
[15] a) Fu, Y.-S.; Du, X.-W.; Kulinich, S. A.; Qiu, J.-S.; Qin, W.-J.; Li, R.; Sun, J.; Liu, J., Stable Aqueous Dispersion of ZnO Quantum Dots with Strong Blue Emission via Simple Solution Route. J. Am. Chem. Soc. 2007, 129, 16029-16033; b) Rubio-Garcia, J.; Dazzazi, A.; Coppel, Y.; -Mascalchi, P.; Salome, L.; Bouhaouss, A.; Kahn, M. L.; Gauffre, F., Transfer of Hydrophobic ZnO Nanocrystals to Water: an Investigation of the Transfer Mechanism and Luminescent Properties. J. Mater. Chem. 2012, 22, 14538-14545.
[16] Chang, J.; Waclawik, E. R., Experimental and Theoretical Investigation of Ligand Effects on the Synthesis of ZnO Nanoparticles. J. Nanopart. Res. 2012, 14:1012.
[17] Shim, M.; Guyot-Sionnest, P., Organic-Capped ZnO Nanocrystals: Synthesis and n-Type Character. J. Am. Chem. Soc. 2001, 123, 11651-11654.
[18] Valdez, C. N.; Schimpf, A. M.; Gamelin, D. R.; Mayer, J. M., Low Capping Group Surface Density on Zinc Oxide Nanocrystals. ACS Nano 2014, 8, 9463-9470.

1. The method of a preparation of zinc oxide nanoparticles, in which an organozinc precursor in an aprotic organic solvent is subjected to an oxidizing agent, characterized in that as the organozinc precursor a compound of the formula [R₂ZnLₙ]ₘ is used, in which R is C1-C5 alkyl, straight or branched, benzyl, phenyl, mesityl, cyclohexyl group, L is low-molecular-weight organic compound containing one Lewis base center of Formula 1 or of Formula 2 or of Formula 3, 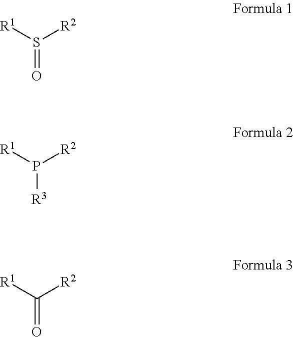
where R¹, R² and R³ are C1-C5 alkyl, straight or branched, phenyl, benzyl, tolyl, mesityl or vinyl group, in which any hydrogen atom may be substituted by fluorine, chlorine, bromine or iodine atom, n is 0, 1 or 2, m is a natural number from 1 to 10.

2. The method of claim 1, characterized in that a solvent with solvating and/or coordinating properties is used as the solvent.

3. The method. of claim 1, characterized in that dimethyl sulfoxide, dibuthyl sulfoxide, tetrahydrofuran, dichloromethane, dioxane, acetonitrile, chloroform, toluene, benzene, hexane, acetone or a mixture thereof is used as the solvent.

4. The method of claim 1, characterized in that, when a liquid compound is used as L, it has a function of both a L-type ligand and an aprotic solvent for the organozinc precursor.

5. The method of claim 1, characterized in that a solvent with the addition of water is used.

6. The method of claim 5, characterized in that the concentration of water in the solvent does not exceed 0.5% w/w.

7. The method of claim 1, characterized in that oxygen, water, atmospheric air or a mixture of thereof is used as the oxidizing agent.

8. The method of claim 1, characterized in that the reaction is carried out at a temperature range from 0° C. to 100° C.

9. The method of claim 1, characterized by the fact that the reaction is carried out at a molar concentration. of the precursor in an organic solvent from 0.01 mol/L to 0.4 mol/L.

10. The method of claim 1, characterized by the fact that the reaction is carried out from 24 to 336 hours.

11. Zinc oxide nanoparticles obtained by the method according to claim 1.

12. Zinc oxide nanoparticles of claim 11 characterized in that are stabilized by neutral short-chain donor organic ligands, wherein neutral short-chain organic donor ligands are compounds of Formula 1 or of Formula 2 or of Formula 3, 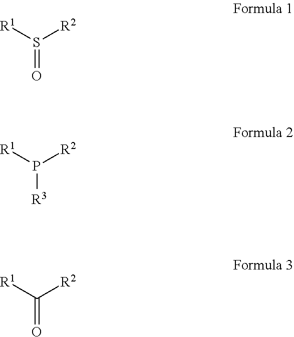
where R¹, R² and R³ are C1-C5 alky straight or branched, phenyl, benzyl, tolyl, mesityl or vinyl group, in which any hydrogen atom may be substituted by fluorine, chlorine, bromine or iodine atom, more preferably neutral short-chain donor organic ligands are sulfoxides, the most preferably dimethyl sulfoxide.

13. Nanoparticles of claim 11, characterized in that the diameter of the zinc oxide nanoparticles is less than equal to 15 nm and is characterized by narrow size distribution.

14. Nanoparticles according to claim 11, characterized that nanoparticles have a wurtzite core structure.

15. Solar cells, UV filters, or materials for use in electronics or in catalysis, comprising the zinc oxide nanoparticles of claim 11.

16. The method of claim 2, characterized in that, when a liquid compound is used as L, it has a function of both a L-type ligand and an aprotic solvent for the organozinc precursor.

17. The method of claim 3, characterized in that, when a liquid compound is used as L, it has a function of both a L-type ligand and an aprotic solvent for the organozinc precursor.

18. The method of claim 1, characterized in that the reaction is carried out at a temperature range from 10° C. to 60° C.

19. The method of claim 1, characterized in that the reaction is carried out at a temperature range from 15° C. to 35° C.
